(19) United States
(12) Patent Application Publication
(10) Pub. No.: US 2024/0130166 A1
(43) Pub. Date: Apr. 18, 2024

(54) DISPLAY DEVICE

(71) Applicant: LG Display Co., Ltd., Seoul (KR)

(72) Inventors: GiSang HONG, Seoul (KR); SungKi KIM, Gyeonggi-do (KR); JongWon LEE, Seoul (KR); YoungWook LEE, Gyeonggi-do (KR); Jungmin KIM, Gyeonggi-do (KR); Hoseung LEE, Gyeonggi-do, (KR)

(21) Appl. No.: 18/484,157

(22) Filed: Oct. 10, 2023

(30) Foreign Application Priority Data
Oct. 14, 2022 (KR) 10-2022-0131918

(51) Int. Cl. H10K 59/122; H10K 59/80

(52) U.S. Cl. CPC H10K 59/122; H10K 59/8792

(57) ABSTRACT

Embodiments of the disclosure relate to a display device. Specifically, there may be provided a display device that comprises a substrate having a plurality of subpixels and an overcoat layer disposed on the substrate, wherein the overcoat layer includes a recess disposed between the subpixels, and wherein a transparent inorganic bank layer and an opaque bank layer are disposed in the recess, thereby preventing outgassing or hydrogen migration, enhancing side light extraction efficiency, reducing or minimizing reflection by external light even without providing a polarizing plate, preventing deterioration of visibility and contrast ratio, and enhancing luminance.

### CROSS-REFERENCE TO RELATED APPLICATION

This application claims priority from Korean Patent Application No. 10-2022-0131918, filed on Oct. 14, 2022, which is hereby incorporated by reference for all purposes as if fully set forth herein.

### BACKGROUND

### Technical Field

Embodiments of the disclosure relate to a display device.

### Description of Related Art

Display devices are widely used as display screens for laptop computers, tablet computers, smartphones, portable display devices, and portable information devices, as well as for televisions or monitors.

Display devices may be divided into reflective display devices and emissive display devices. The reflective display device is a display device that displays information by reflecting natural light or light from an external light source of the display device to the display device. The emissive display device displays information using the light generated from light emitting elements or a light source embedded in the display device.

### BRIEF SUMMARY

In the conventional display device, the light emitted from an organic light emitting layer and traveling to the side disappears at a bank layer without being extracted to the outside because of an electrode (e.g., a first or a second electrode adjacent to the organic light emitting layer), thereby reducing light efficiency. Further, reflection of external light may deteriorate visibility and contrast ratio.

Thus, the inventors of the disclosure have invented a display device that comprises a substrate having a plurality of subpixels and an overcoat layer disposed on the substrate, wherein the overcoat layer includes a recess disposed between the subpixels, and wherein a transparent inorganic bank layer and an opaque bank layer are disposed in the recess, thereby preventing outgassing or hydrogen migration, enhancing side light extraction efficiency, reducing or minimizing reflection by external light even without providing a polarizing plate, preventing deterioration of visibility and contrast ratio, and enhancing luminance.

Embodiments of the disclosure may provide a display device capable of preventing outgassing or hydrogen migration, enhancing side light extraction efficiency, reducing or minimizing reflection by external light even without providing a polarizing plate, preventing deterioration of visibility and contrast ratio, and enhancing luminance.

Embodiments of the disclosure may provide a display device capable of reducing parasitic capacitance that occurs between a signal line and the second electrode by having a transparent inorganic bank layer and an opaque bank layer between the signal line and the second electrode in the non-emission area.

Embodiments of the disclosure may provide a display device comprising a substrate having a plurality of subpixels and an overcoat layer disposed on the substrate, wherein the overcoat layer includes a recess disposed between the subpixels, and wherein a transparent inorganic bank layer and an opaque bank layer are disposed in the recess.

Embodiments of the disclosure may provide the display device, wherein the transparent inorganic bank layer is disposed on an inclined surface and a lower surface of the recess.

Embodiments of the disclosure may provide the display device, wherein the opaque bank layer is disposed on an upper surface of the transparent inorganic bank layer to be spaced apart from the inclined surface of the recess in an area corresponding to the lower surface of the recess.

Embodiments of the disclosure may provide a display device comprising a plurality of subpixels including an emission area and a non-emission area and a substrate on which a plurality of signal lines defining the plurality of subpixels are disposed, wherein the emission area includes a recess positioned between the subpixels, wherein the non-emission area includes an overcoat layer disposed on the plurality of signal lines and the substrate, a transparent inorganic bank layer disposed on the overcoat layer, an opaque bank layer disposed on the transparent inorganic bank layer, and a second electrode disposed on the opaque bank layer.

According to embodiments of the disclosure, there may be provided a display device capable of preventing outgassing or hydrogen migration and enhancing side light extraction efficiency.

According to embodiments of the disclosure, there may be provided a display device capable of reducing or minimizing reflection by external light even without providing a polarizing plate, preventing deterioration of visibility and contrast ratio, and enhancing luminance.

According to embodiments of the disclosure, there may be provided a display device capable of reducing the parasitic capacitance that occurs between the signal line and the second electrode.

### DESCRIPTION OF THE SEVERAL VIEWS OF THE DRAWINGS

The above and other objects, features, and advantages of the disclosure will be more clearly understood from the following detailed description, taken in conjunction with the accompanying drawings, in which:

FIG. 1 is a view schematically illustrating a system configuration of a display device according to embodiments of the disclosure;

FIG. 2 is a view illustrating a schematic planar structure of a pixel structure disposed on a display panel of a display device according to embodiments of the disclosure;

FIG. 3 is a cross-sectional view illustrating an example structure, taken along line A-A′ of FIG. 2;

FIG. 4 is a cross-sectional view illustrating another example structure, taken along line A-A′ of FIG. 2;

FIGS. 5A, 5B, and 5C are views illustrating a process for forming a display panel according to embodiments of the disclosure;

FIG. 6A is a view illustrating an example of a cross-sectional structure for describing light extraction failure;

FIG. 6B is a view illustrating an example of a cross-sectional structure for describing reflection failure by a cathode electrode;

FIG. 7 is a cross-sectional view illustrating an example structure, taken along line B-B′ of FIG. 2;

FIG. 8 is a cross-sectional view illustrating another example structure, taken along line B-B′ of FIG. 2; and

FIG. 9 is a view illustrating an emission area and a non-emission area of a subpixel in a display device according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

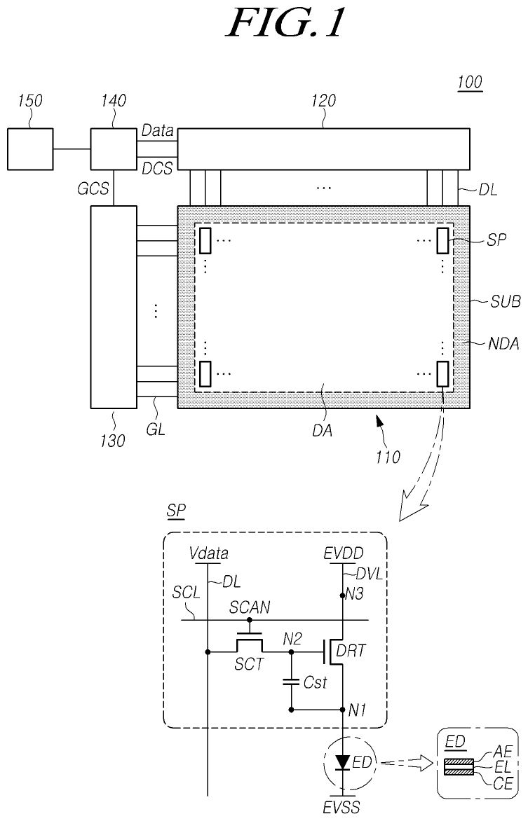

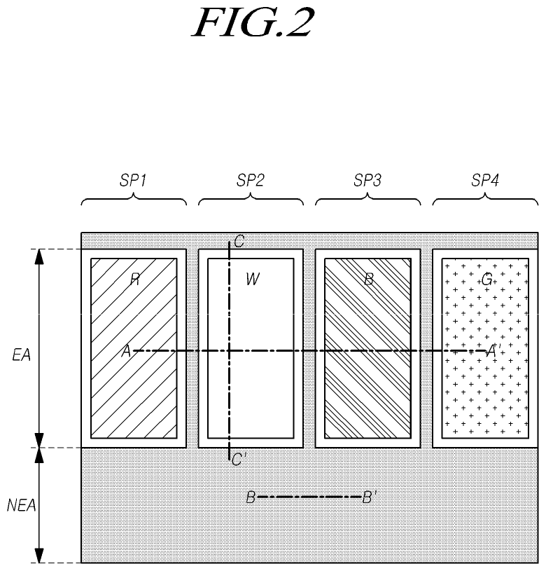

FIG. 1 is a view schematically illustrating a system configuration of a display device according to embodiments of the disclosure. FIG. 2 is a view illustrating a schematic planar structure of a pixel structure disposed on a display panel of a display device according to embodiments of the disclosure.

Referring to FIG. 1, a display driving system of a display device 100 according to embodiments of the disclosure may include a display panel 110 and display driving circuits for driving the display panel 110.

The display panel 110 may include a display area DA in which images are displayed and a non-display area NDA in which no image is displayed. The display panel 110 may include a plurality of subpixels SP disposed on a substrate SUB for image display. The display panel 110 may include a plurality of signal lines disposed on the substrate SUB. For example, the plurality of signal lines may include data lines DL, gate lines GL, driving voltage lines, and the like.

Each of the plurality of data lines DL is disposed while extending in a first direction (e.g., a column direction or a row direction), and each of the plurality of gate lines GL is disposed while extending in a direction crossing the first direction.

The display driving circuits may include a data driving circuit 120, a gate driving circuit 130, and a controller 140 controlling the data driving circuit 120 and the gate driving circuit 130.

The data driving circuit 120 may output data signals (also referred to as data voltages) corresponding to an image signal to the plurality of data lines DL. The gate driving circuit 130 may generate gate signals and output the gate signals to the plurality of gate lines GL. The controller 140 may convert the input image data input from an external host 150 to meet the data signal format used in the data driving circuit 120 and supply the converted image data to the data driving circuit 120.

The data driving circuit 120 may include one or more source driver integrated circuits. For example, each source driver integrated circuit may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 130 may be connected to the display panel 110 by a tape automatic bonding (TAB) method, connected to a bonding pad of the display panel 110 by a COG or COP method, connected to the display panel 110 by a COF method, or may be formed in the non-display area NDA of the display panel 110 by a gate in panel (GIP) method.

Referring to FIG. 1, in the display device 100 according to embodiments of the disclosure, each subpixel SP may include a light emitting element ED and a pixel driving circuit SPC for driving the light emitting element ED. The pixel driving circuit SPC may include a driving transistor DRT, a scan transistor SCT, and a storage capacitor Cst.

The driving transistor DRT may control a current flowing to the light emitting element ED to drive the light emitting element ED. The scan transistor SCT may transfer the data voltage Vdata to the second node N2 which is the gate node of the driving transistor DRT. The storage capacitor Cst may be configured to maintain a voltage for a predetermined period of time.

The light emitting element ED may include an anode electrode AE and a cathode electrode CE, and a light emitting layer EL positioned between the anode electrode AE and the cathode electrode CE. The anode electrode AE may be a pixel electrode involved in forming the light emitting element ED of each subpixel SP and may be electrically connected to the first node N1 of the driving transistor DRT. The cathode electrode CE may be a common electrode involved in forming the light emitting elements ED of all the subpixels SP, and a ground voltage EVSS may be applied thereto.

For example, the light emitting element ED may be an organic light emitting diode OLED, an inorganic light emitting diode (LED), or a quantum dot light emitting element, which is a self-luminous semiconductor crystal.

If the display device 100 according to embodiments of the disclosure is an OLED display, each subpixel SP may include an organic light emitting diode (OLED), which by itself emits light, as the light emitting element. If the display device 100 according to embodiments of the disclosure is a quantum dot display, each subpixel SP may include a light emitting element formed of a quantum dot, which is a self-luminous semiconductor crystal. If the display device 100 according to embodiments of the disclosure is a micro LED display, each subpixel SP may include a micro LED, which is self-emissive and formed of an inorganic material, as the light emitting element.

The driving transistor DRT is a transistor for driving the light emitting element ED, and may include a first node N1, a second node N2, and a third node N3. The first node N1 may be a source node or a drain node, and may be electrically connected to the anode electrode AE of the light emitting element ED. The second node N2 is a gate node and may be electrically connected to the source node or drain node of the scan transistor SCT. The third node N3 may be a drain node or a source node, and may be electrically connected to a driving voltage line DVL that supplies the driving voltage EVDD. For convenience of description, in the example described below, the first node N1 may be a source node and the third node N3 may be a drain node.

The scan transistor SCT may switch the connection between the data line DL and the second node N2 of the driving transistor DRT. In response to the scan signal SCAN supplied from the scan line SCL which is a kind of the gate line GL, the scan transistor SCT may control connection between the second node N2 of the driving transistor DRT and a corresponding data line DL among the plurality of data lines DL.

The storage capacitor Cst may be configured between the first node N1 and second node N2 of the driving transistor DRT.

The structure of the subpixel SP illustrated in FIG. 1 is merely an example for description, and may further include one or more transistors, or one or more storage capacitors. The plurality of subpixels SP may have the same structure, or some of the plurality of subpixels SP may have a different structure. Each of the driving transistor DRT and the scan transistor SCT may be an n-type transistor or a p-type transistor.

The display device 100 according to embodiments of the disclosure may have a top emission structure or a bottom emission structure. The bottom emission structure is described below as an example. For example, in the case of the bottom emission structure, the anode electrode AE may be a transparent conductive film, and the cathode electrode CE may be a reflective metal.

Referring to FIG. 2, a display device 100 according to embodiments includes a plurality of subpixels SP1 to SP4, and each subpixel SP1 to SP4 includes an emission area EA that emits light for displaying and a non-emission area NEA other than the emission area.

The display device 100 according to embodiments includes a bank layer to partition each of the subpixels SP1 to SP4.

In the subpixel structure of the display device 100 according to embodiments of the disclosure also includes a “signal line connection structure” that is related to connection of each subpixel to several signal lines, such as the data line DL, gate line GL, driving voltage line DVL, and reference voltage line RVL.

The signal lines may include not only the data line DL for supplying the data voltage Vdata to each subpixel and the gate line GL for supplying the scan signal but also a reference voltage Vref for supplying the reference voltage Vref to each subpixel and a driving voltage line DVL for supplying the driving voltage EVDD.

In the disclosure and drawings, the subpixel connected to the 4n−3th data line DL(4n−3), the subpixel connected to the 4n−2th data line DL(4n−2), the subpixel connected to the 4n−1th data line DL(4n−1), and the subpixel connected to the 4nth data line DL(4n) may be, e.g., a red (R) subpixel, a white (W) subpixel, a blue (W) subpixel, and a green (G) subpixel, respectively.

However, without limitations thereto, the red (R) subpixel, the white (W) subpixel, the blue (B) subpixel, and the green (G) subpixel may be arranged in other various orders. A pixel structure having the order of the red (R) subpixel SP1, the white (W) subpixel SP2, the blue (B) subpixel SP3, and the green (G) subpixel SP4 is described below.

As described above, when the default unit of the signal line connection structure includes four subpixels SP1 to SP4 connected to four data lines DL(4n−3), DL(4n−2), DL(4n−1), and DL(4n), one reference voltage line RVL for supplying the reference voltage Vref and two driving voltage lines DVL for supplying the driving voltage EVDD may be formed for the four subpixels SP1 to SP4. The four data lines DL(4n−3), DL(4n−2), DL(4n−1), and DL(4n) are connected to the four subpixels SP1 to SP4, respectively. Further, one gate line GL(m) (where 1<m≤M) is connected to the four subpixels SP1 to SP4.

In the display device 100 according to embodiments of the disclosure, the organic light emitting diode OLED emitting white (W) light is commonly disposed in each subpixel, and a red (R) color filter, a blue (B) color filter, and a green (G) color filter are disposed in the red (R) subpixel SP1, the blue (B) subpixel SP3, and the green (G) subpixel SP4, respectively. No separate color filter is disposed in the white (W) subpixel SP2.

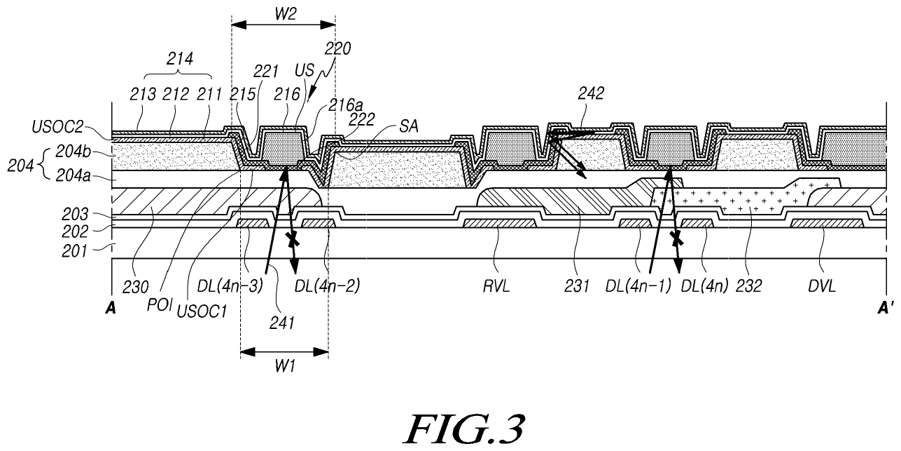

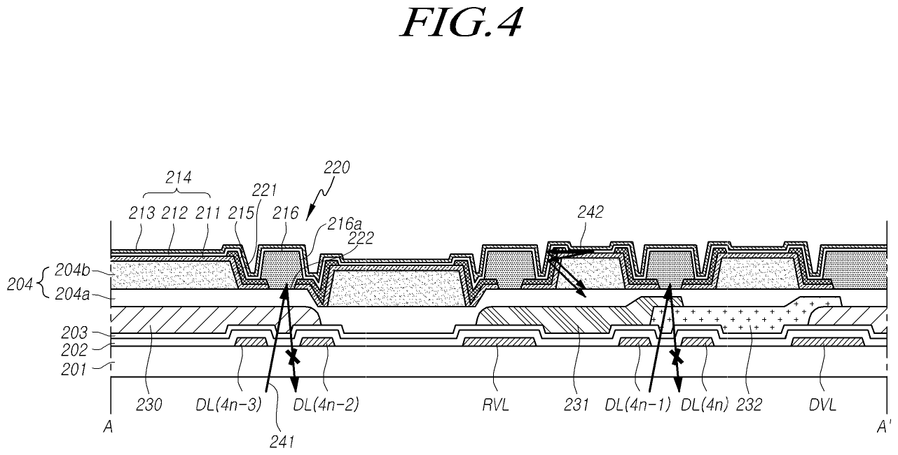

FIGS. 3 and 4 are cross-sectional views illustrating a display device according to embodiments of the disclosure. Specifically, FIG. 3 is a view illustrating an example of a cross-sectional structure of portion A-A′ shown in FIG. 2, and FIG. 4 is a view illustrating another example of the cross-sectional structure of portion A-A′ shown in FIG. 2.

Referring to FIGS. 3 and 4, the display device 100 according to embodiments of the disclosure may include a substrate 201 on which a plurality of subpixels is arranged and an overcoat layer 204 disposed on the substrate 201. The overcoat layer 204 may include a recess 220 disposed between the subpixels, and a transparent inorganic bank layer 215 and an opaque bank layer 216 may be disposed in the recess 220.

A plurality of subpixels may be disposed on the substrate 201. The substrate 201 may be selected as a material for forming an element having an improved mechanical strength or dimensional stability. The substrate 201 may be not only a glass substrate, but also a plastic substrate including polyethylene terephthalate (PET), polyethylene naphthalate (PEN), polyimide, or the like.

A plurality of signal lines DL, RVL, and DVL may be disposed on the substrate 201, and a buffer layer 202 may be disposed on the plurality of signal lines DL, RVL, and DVL.

The buffer layer 202 serves to protect a thin film transistor (not shown) formed in a subsequent process from impurities such as alkali ions flowing out of the substrate 201. The buffer layer 202 may be a single layer of silicon oxide (SiOx) or silicon nitride (SiNx) or multiple layers thereof.

A passivation layer 203 may be disposed on the buffer layer 202.

The passivation layer 203 is an insulation film for protecting elements thereunder, and may be a single layer of silicon oxide (SiOx) or silicon nitride (SiNx) or multiple layers thereof. Also, the passivation layer PAS may be omitted.

A color filter may be disposed on the passivation layer 203. The color filter may be disposed to correspond to each subpixel SP1 to SP4 area.

A red (R) color filter 230 may be disposed in the red (R) subpixel SP1 area, and a blue (B) color filter 231 and a green (G) color filter 232 may be disposed in the blue (B) subpixel SP3 and the green (G) subpixel SP4, respectively.

A separate color filter may not be disposed in the white (W) subpixel SP2, and an overcoat layer 204 may be disposed. Since the overcoat layer 204, the passivation layer 203, and the buffer layer 202 stacked in the white (W) subpixel SP2 area are formed of a transparent material, a separate color filter may not be disposed.

The overcoat layer 204 may be disposed on the color filter and the passivation layer 203.

The overcoat layer 204 may have an area where a partial step is formed due to patterns formed below. Further, the overcoat layer 204 may provide a flat surface for mitigating a height step of the structure thereunder.

In the display device according to embodiments of the disclosure, a recess 220 may be formed by utilizing a height step formed in the overcoat layer 204.

The overcoat layer 204 may prevent outgassing, generated in color filters disposed respectively corresponding to the subpixel, from being transferred to the organic light emitting diode 214 disposed on the overcoat layer 204.

The overcoat layer 204 may include a first overcoat layer 204a and a second overcoat layer 204b disposed on the first overcoat layer 204a.

The first overcoat layer 204a may be disposed on the color filter and the passivation layer 203 without being disconnected. For instance, FIG. 3 illustrates that the first overcoat layer 204a is continuously and contiguously extended across the subpixels SP1 to SP4. This is contrary to the second overcoat layer 204b which is illustrated as being spaced apart from each other in the cross-section of FIG. 3. In this case, the first overcoat layer 204a may have a step SA between the area where the color filter is disposed and the area where the color filter is not disposed. In particular, the first overcoat layer 204a has a step SA between the red pixel and the white pixel. The step SA is in an area between adjacent second overcoat layers 204b. Differently put, the step SA at least partially overlaps with the recess 220.

The second overcoat layer 204b may be disposed on the first overcoat layer 204a, and may be disposed in the opening of each of the subpixels SP1 to SP4 partitioned by the bank layer 221.

The second overcoat layer 204b may be formed by forming the front surface on the first overcoat layer 204a and then etching between the subpixels SP1 to SP4. However, this is only one method of forming the second overcoat layer 204b and other methods may be utilized.

Further, the second overcoat layer 204b may be formed on the first overcoat layer 204a in an area corresponding to an opening of each of the subpixels SP1 to SP4.

The overcoat layers 204, 204a, and 204b may be formed of an organic film such as an acryl resin, an epoxy resin, a phenolic resin, a polyamide resin, a polyimide resin, or the like.

The organic light emitting diode 214 may be disposed on the overcoat layer 204.

The organic light emitting diode 214 may include a first electrode 211, an organic light emitting layer 212, and a second electrode 213.

An encapsulation layer (not shown) in which a plurality of organic films and inorganic films are stacked may be further formed on the organic light emitting diode 214.

The first electrode 211 is a pixel electrode serving as an anode, and may be independently disposed in each of the subpixels SP1 to SP4.

The first electrode 211 may be formed of a metal, an alloy thereof, and a combination of a metal and an oxide metal, and may include a transparent conductive material.

For example, the first electrode 211 may be formed of one of ITO, IZO, ITZO, ITO/APC/ITO, AlNd/ITO, Ag/ITO, or ITO/APC/ITO.

The organic light emitting layer 212 may include multiple layers of a hole injection layer, a hole transport layer, a light emitting material layer, an electron transport layer, and an electron injection layer to increase light emission efficiency.

The second electrode 213 is a common electrode serving as a cathode, and may be commonly disposed in all subpixels SP1 to SP4.

The second electrode 213 may be a transflective electrode or a reflective electrode.

For example, the second electrode 213 may be any one selected from the group consisting of silver (Ag), aluminum (Al), magnesium (Mg), chromium (Cr), titanium (Ti), nickel (Ni), tungsten (W), gold (Au), tantalum (Ta), copper (Cu), cobalt (Co), iron (Fe), molybdenum (Mo), and platinum (Pt), or an alloy of the metals.

The overcoat layer 204 may include a recess 220. The recess 220 may be positioned and disposed between the subpixels SP1 to SP4.

The recess 220 may be formed by etching an area where the recess 220 is to be disposed after forming the overcoat layer 204.

Further, an area where the overcoat layer 204 is not formed may be used as a recess by forming the overcoat layer 204 in the opening of each subpixel SP1 to SP4.

The recess 220 may be disposed between the second overcoat layers 204b positioned in the areas (e.g., area between adjacent second overcoat layers 204b) respectively corresponding to the subpixels SP1 to SP4.

For example, the recess 220 may be formed between the subpixels SP1 to SP4 by forming the second overcoat layer 204b at the position corresponding to the opening of each subpixel SP1 to SP4 after forming the first overcoat layer 204a on the front surface of the substrate.

The recess 220 may include an inclined surface 221 and a lower surface 222. As shown in FIG. 3, the inclined surface 221 of the recess 220 corresponds to an inclined side surface (or simply a side surface) of the second overcoat layer 204b. The lower surface 222 of the recess 220 corresponds to an upper surface (or a top surface) of the first overcoat layer 204a.

In the recess 220, a width W2 of an upper side of the recess 220 may be larger than a width W1 of a lower side of the recess 220. In other words, the width of the recess 220 may increase away from the substrate.

Further, as described above, the inclined surface 221 of the recess 220 may correspond to the side surface of the second overcoat layer 204b, and the lower surface 222 of the recess 220 may correspond to a portion of the upper surface of the first overcoat layer 204b.

A first electrode 214 may be disposed to extend on the inclined surface 221 of the recess 220, and the first electrode 214 may be disposed to extend on a portion of the lower surface 222 of the recess 220. In other words, the first electrode may be disposed to be disconnected on the lower surface 222 of the recess 220.

A transparent inorganic bank layer 215 and an opaque bank layer 216 on the transparent inorganic bank layer 215 may be disposed in the recess 220.

The transparent inorganic bank layer 215 may be disposed on the inclined surface 221 and the lower surface 222 of the recess 220.

The transparent inorganic bank layer 215 may be disposed to extend from the inclined surface 221 of the recess 220 to a portion of the upper surface of the overcoat layer 214.

The transparent inorganic bank layer 215 may include a first portion disposed to extend on a portion of the upper surface of the overcoat layer 214 and a second portion disposed on the inclined surface 221 of the recess 220.

In this case, the width of the first portion projected on the plane may be wider than the width of the second portion projected on the plane.

The transparent inorganic bank layer 215 may be disposed to contact a portion of the upper surface of the first overcoat layer 214a on the lower surface 222 of the recess 220.

The transparent inorganic bank layer 215 may be disposed on the first electrode 211 and the lower surface 222 of the recess 220 in the recess 220, and the transparent inorganic bank layer 215 may be disposed in an area overlapping the first electrode 211 in the recess 220.

The transparent inorganic bank layer 215 may be disposed to be disconnected on the lower surface 222 of the recess 220.

The first electrode 211 may be disposed to extend up to a portion of the lower surface 222 of the recess 220, and the transparent inorganic bank layer 215 may be disposed up to the extension of the first electrode 211 but not disposed in the disconnected portion of the first electrode 211. This structure may be formed by sequentially forming the first electrode 211 and the transparent inorganic bank layer 215 on the overcoat layer 204 and simultaneously patterning the first electrode 211 and the transparent inorganic bank layer 215.

The transparent inorganic bank layer 215 may include a single layer or multiple layers of silicon nitride (SiNx), silicon oxide (SiOx), silicon oxynitride (SiOxNy), aluminum oxide (AlOx), and aluminum oxynitride (AlOxNy).

For example, the transparent inorganic bank layer 215 may include silicon dioxide (silica or silicon dioxide (SiO₂).

The opaque bank layer 216 may be spaced apart from the inclined surface 221 of the recess 220 and disposed on the upper surface of the transparent inorganic bank layer 215 in the area corresponding to the lower surface 222 of the recess 220.

The transparent inorganic bank layer 215 may be disposed to be disconnected on the lower surface 222 of the recess 220, and the opaque bank layer 216 may be disposed to contact the overcoat layer 204 on the lower surface 222 of the recess 220. In this case, the opaque bank layer 216 may be disposed to contact a portion of the upper surface of the first overcoat layer 204a.

The opaque bank layer 216 may be disposed to contact a portion of the transparent inorganic bank layer 215 on the lower surface 222 of the recess 220.

The opaque bank layer 216 may have a regular tapered shape.

Accordingly, the inclined surface 221 of the recess 220 and the side surface 216a of the opaque bank layer may form a V shape.

A second electrode 213 may be disposed on the opaque bank layer 216. In other words, the second electrode 213 may be disposed on the side surface 216a and the upper surface US of the opaque bank layer.

An organic light emitting layer 212 may be disposed between the opaque bank layer 216 and the second electrode 213.

At least one color filter 230, 231, and 232 may be disposed to extend while overlapping the area where the opaque bank layer 216 is disposed. In this case, the extending color filters 230, 231, and 232 may be stacked on each other and disposed to overlap the area where the opaque bank layer 216 is disposed.

Since the V-shaped lower side which is formed by the inclined surface 221 of the recess 220 and the side surface 216a of the opaque bank layer is positioned lower than the organic light emitting layer 212, the light 242 emitted from the organic light emitting layer 212 and traveling sideways may be reflected by the second electrode 213 and extracted to the outside, so that side light extraction efficiency may be enhanced.

The opaque bank layer 216 may include a colored material to reduce or minimize reflection by external light, thereby increasing optical density (OD) indicating the degree of light blocking. When the optical density increases, reflection by external light may be reduced or minimized, and thus a polarizing plate may be excluded.

The optical density of the opaque bank layer 216 may be 4 or more, and when the optical density of the opaque bank layer 216 is less than 4, a low reflection effect by external light may be reduced.

Here, the optical density (OD) means a negative logarithmic value of transmitted light I with respect to incident light I0 when light is transmitted through a certain material, as follows.

OD=−log(I/I₀)

The thickness of the opaque bank layer 216 may be 0.5 μm or more and 2.5 μm or less, and the width of the opaque bank layer 216 may be 10 μm or more and 14 μm or less.

The opaque bank layer 216 may include at least one selected from among carbon black, black pigment, black dye, black resin, graphite powder, gravure ink, black spray, black enamel, or the like.

As the structure in which the transparent inorganic bank layer 215 and the opaque bank layer 216 are stacked is applied to the recess 220, it is possible to prevent transfer to the organic light emitting diode 214 of the outgassing generated when forming the transparent organic bank layer or black matrix by the transparent inorganic bank layer 215 and to stop hydrogen migration.

As the structure in which the transparent inorganic bank layer 215 and the opaque bank layer 216 are stacked is applied to the recess 220, it is possible to reduce or minimize reflection by external light by the opaque bank layer 216 to prevent deterioration of visibility and contrast ratio, enhance luminance, and exclude a polarizing plate.

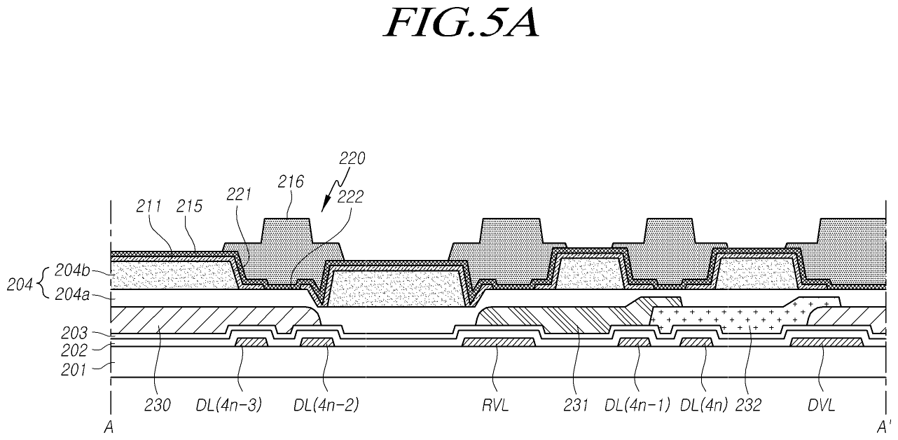

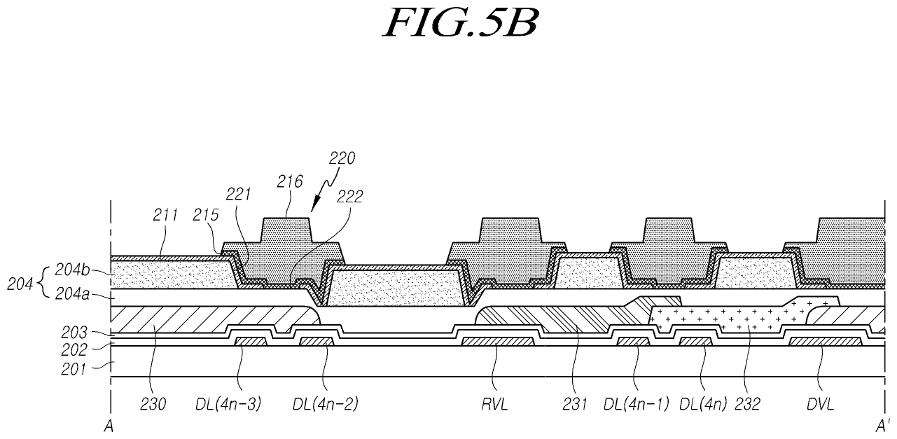

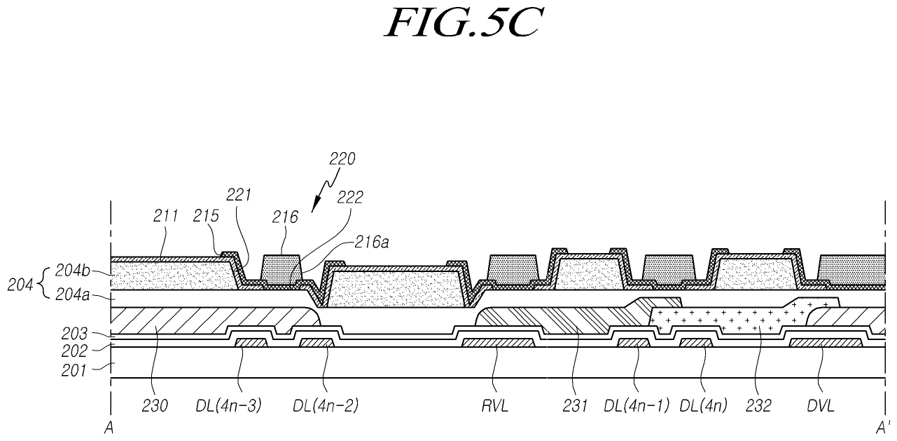

FIGS. 5A, 5B, and 5C are views illustrating a process for forming a display panel according to embodiments of the disclosure;

Referring to FIG. 5A, a second overcoat layer 204b is disposed on the first overcoat layer 204a to form a recess 220.

An electrode material is deposited on the first overcoat layer 204a and the second overcoat layer 204b and then patterned to form the first electrode 211.

A transparent inorganic bank layer 215 is deposited on the first electrode 211 and the first overcoat layer 204a to form the transparent inorganic bank layer 215.

An opaque bank layer 216 is formed on the transparent inorganic bank layer 215 by a halftone process.

Although not shown, after sequentially forming an electrode material and a transparent inorganic layer on the first overcoat layer 204a and the second overcoat layer 204b, the electrode material and the transparent inorganic layer are simultaneously etched to be simultaneously disconnected on the lower surface of the recess 220, forming the first electrode 211 and the transparent inorganic bank layer 215.

Referring to FIG. 5B, a pattern is formed by etching the transparent inorganic bank layer 215 using the opaque bank layer 216 as a mask.

If the transparent inorganic bank layer 215 is patterned using the opaque bank layer 216 as a mask, it is possible to mitigate a reduction in aperture ratio due to the alignment tolerance.

Referring to FIG. 5C, a pattern of the opaque bank layer 216 is formed by ashing the opaque bank layer 216.

Thereafter, the organic light emitting layer 212 and the second electrode 213 are sequentially stacked to manufacture the display device illustrated in FIG. 3.

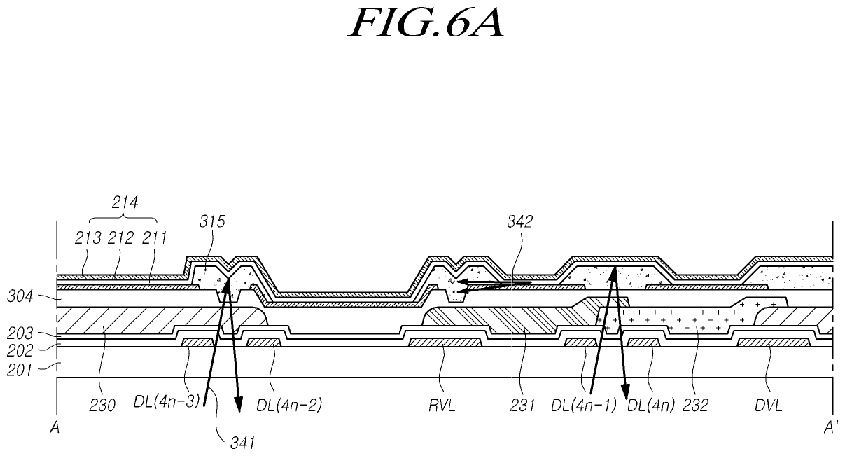

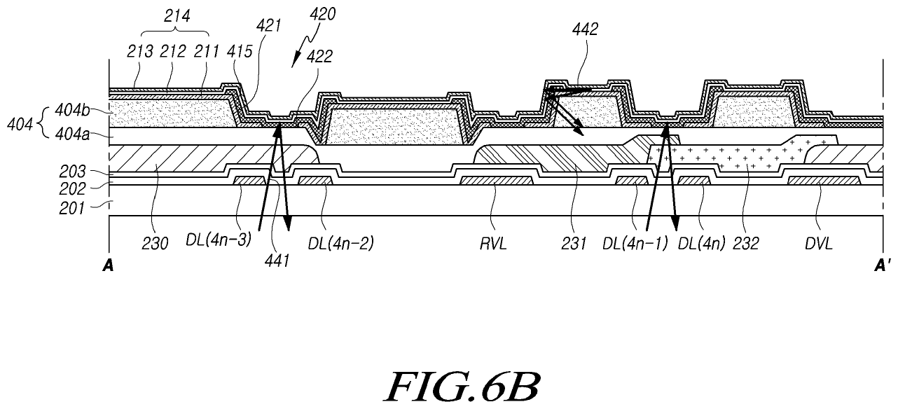

FIG. 6A is a view illustrating an example of a cross-sectional structure for describing light extraction failure. FIG. 6B is a view illustrating an example of a cross-sectional structure for describing reflection failure by a cathode electrode.

Referring to FIG. 6A, the light 342 emitted from the organic light emitting layer 212 and traveling sideways is not extracted to the outside because the second electrode 213, which is a reflective electrode, is flat, but disappears on the transparent bank layer 315, reducing light efficiency. Further, since the external light 341 enters between data lines DL (more specifically, as shown in FIG. 6A, between DL(4n−3) and DL(4n−2)) and is reflected by the second electrode 213, which is a reflective electrode, accordingly, visibility and contrast ratio may deteriorate.

Referring to FIG. 6B, since the light 442 emitted from the organic light emitting layer 212 and traveling sideways may be reflected by the second electrode 213 and extracted to the outside, the side light extraction efficiency may be enhanced. However, since the external light 441 enters between data lines DL (more specifically, as shown in FIG. 6B, between DL(4n−3) and DL(4n−2)) and is reflected by the second electrode 213, which is a reflective electrode, accordingly, deterioration of visibility and contrast ratio still exists.

However, according to embodiments of the disclosure, the light 242 emitted from the organic light emitting layer 212 and traveling sideways may be reflected by the second electrode 213 and extracted to the outside, so that the side light extraction efficiency is enhanced. Further, even when external light 241 enters between data lines DL (more specifically, as shown in FIG. 3, between DL(4n−3) and DL(4n−2)), it may be absorbed by the opaque bank layer 216 disposed on the transparent inorganic bank layer 215, thereby reducing or minimizing reflection by the external light 241. The “X” labeled across the arrow that is in opposite direction of external light 241 indicates that light does not reflect back due to the opaque bank layer 216 disposed on the transparent inorganic bank layer 215 that absorbs external light 241.

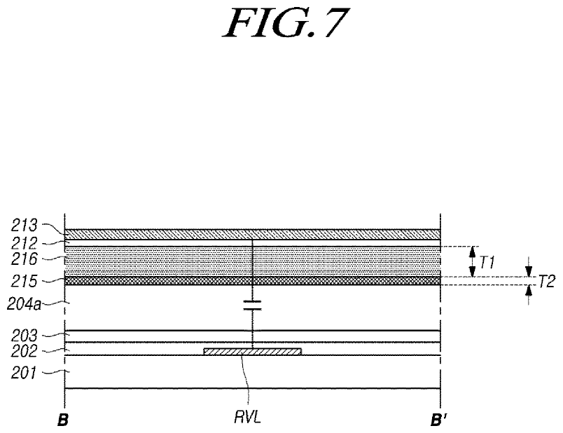

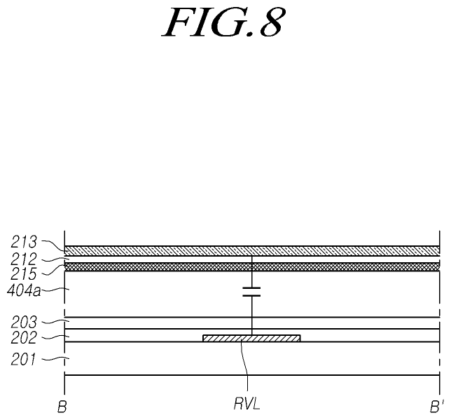

FIG. 7 is a cross-sectional view illustrating an example structure, taken along line B-B′ of FIG. 2. FIG. 8 is a cross-sectional view illustrating another example structure, taken along line B-B′ of FIG. 2.

Unnecessary parasitic capacitance may occur between the second electrode disposed in the non-emission area and the signal line. Since such parasitic capacitance may increase the load of various signals, it is beneficial to reduce or minimize the magnitude of the parasitic capacitance.

Referring to FIGS. 7 and 8, parasitic capacitance may occur between the second electrode 213 and the reference voltage line RVL, which is one of several signal lines.

The display device 100 according to embodiments of the disclosure, shown in FIG. 7 includes a transparent inorganic bank layer 215 and an opaque bank layer 216 stacked between the second electrode 213 and the reference voltage line RVL in the opaque area (which at least partially overlaps with the non-emission area NEA).

The thickness of the opaque bank layer 216 (i.e., thickness T1) is not smaller than the thickness of the transparent inorganic bank layer 215 (i.e., thickness T2).

In contrast, the display device disclosed in FIG. 8 has a structure in which the transparent inorganic bank layer 215 is stacked between the second electrode 413 and the reference voltage line RVL.

The thickness between the second electrode 213 and the reference voltage line RVL of the display device 100 according to embodiments of the disclosure is larger, by the thickness of the opaque bank layer 216, than the thickness between the second electrode 413 and the reference voltage line RVL of the display device shown in FIG. 8, so that the generation of parasitic capacitance may be reduced.

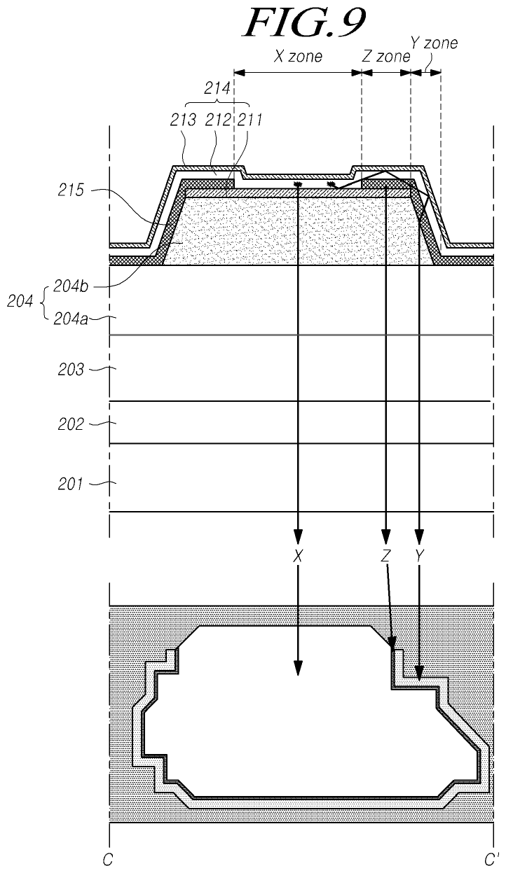

FIG. 9 is a view illustrating an emission area and a non-emission area of a subpixel in a display device according to embodiments of the disclosure.

Referring to FIG. 9, the subpixel may include an X zone which is an emission area and a Y zone and a Z zone which are non-emission areas of the subpixel.

The X zone is an opening area where the light emitting element 210 including the first electrode 211, the organic light emitting layer 212, and the second electrode 213 is disposed. In the X zone, light emitted from the organic light emitting layer 212 may be directly extracted to the outside.

The Y zone is an area having a second portion in which the transparent inorganic bank layer 215 is disposed on the inclined surface of the recess, and includes the transparent inorganic bank layer 215 and the second electrode 213 which is a reflective electrode. The Y zone includes the second electrode 213, which is a reflective electrode, so that light traveling sideways from the organic light emitting layer 212 of the emission area may be reflected by the second electrode 213 and extracted to the outside.

The Z zone is an area where the transparent inorganic bank layer 215 has a first portion disposed to extend on a portion of the upper surface of the overcoat layer 214, and includes a first electrode 211, a transparent inorganic bank layer 212, an organic light emitting layer 212, and a second electrode 213. In the Z zone, since the transparent inorganic bank layer 215 is disposed between the first electrode 211 and the organic light emitting layer 212 so that light may not be generated in the organic light emitting layer 212, and since the organic light emitting layer 213 in the emission area and the second electrode 213 are disposed parallel to each other, it may be difficult for light traveling sideways to be reflected by the second electrode 213 and extracted to the outside.

Referring to FIG. 9, in the subpixel, the width of the first portion included in the Z zone projected onto the plane is wider than the width of the second portion included in the Y zone projected onto the plane. In other words, the width of each area projected onto the plane in the subpixel has a relationship of X zone >Z zone >Y zone.

On the other hand, when the subpixel emits light, the emission width of each area projected on the plane has a relationship of X zone >Y zone >Z zone. As the light emitted from the organic light emitting layer 212 is directly extracted to the outside, the light is partially emitted not only in the Y zone but also in the Z zone, and as the light traveling sideways from the organic light emitting layer 212 in the emission area is reflected by the second electrode 213 and extracted to the outside, the light is partially emitted not only in the Y zone but also in the Z zone, resulting in the Z zone having the narrowest width.

Embodiments of the disclosure described above are briefly described below.

A display device according to embodiments of the disclosure may comprise a substrate having a plurality of subpixels, an overcoat layer disposed on the substrate, the overcoat layer including a recess disposed between the subpixels and a transparent inorganic bank layer and an opaque bank layer disposed in the recess.

The transparent inorganic bank layer may be disposed on an inclined surface and a lower surface of the recess.

The opaque bank layer may be disposed on an upper surface of the transparent inorganic bank layer to be spaced apart from the inclined surface of the recess in an area corresponding to the lower surface of the recess.

The transparent inorganic bank layer may be disposed to be disconnected on the lower surface of the recess.

The transparent inorganic bank layer may extend on a portion of an upper surface of the overcoat layer.

The transparent inorganic bank layer may include a first portion disposed to extend on the portion of the upper surface of the overcoat layer and a second portion disposed on the inclined surface of the recess, and a width of the first portion projected onto a plane may be larger than a width of the second portion projected onto a plane.

The overcoat layer may include a first overcoat layer, and a second overcoat layer positioned on the first overcoat layer in an area corresponding to the subpixels.

The recess may be disposed between the second overcoat layers positioned in the area corresponding to the subpixels.

The transparent inorganic bank layer may contact the first overcoat layer on the lower surface of the recess.

The opaque bank layer may contact the first overcoat layer on the lower surface of the recess.

The transparent inorganic bank layer may include at least one selected from the group consisting of silicon nitride, silicon oxide, silicon oxynitride, aluminum oxide, and aluminum oxynitride.

The opaque bank layer may include at least one selected from the group consisting of carbon black, black pigment, black dye, black resin, graphite powder, gravure ink, black spray, and black enamel.

The plurality of subpixels may include at least one colored subpixel among red, green, and blue subpixels, and a color filter having a color corresponding to the colored subpixel may be disposed between the substrate and the overcoat layer.

A first electrode, an organic light emitting layer, and a second electrode may be disposed on the overcoat layer.

The first electrode may be disposed to extend on a portion of the inclined surface and the upper surface of the recess, and the transparent inorganic bank layer may be disposed on the first electrode and the lower surface of the recess in the recess.

The opaque bank layer may be disposed on an upper surface of the transparent inorganic bank layer and spaced apart from the inclined surface of the recess, and the second electrode may be disposed on the opaque bank layer.

The transparent inorganic bank layer may be disposed in an area overlapping the first electrode in the recess.

The first electrode may be a transparent electrode, and the second electrode may be a reflective electrode.

A display device according to embodiments of the disclosure may comprise a plurality of subpixels including an emission area and a non-emission area and a substrate on which a plurality of signal lines defining the plurality of subpixels are disposed, the emission area may include a recess positioned between the subpixels, and the non-emission area may include an overcoat layer disposed on the plurality of signal lines and the substrate, a transparent inorganic bank layer disposed on the overcoat layer, an opaque bank layer disposed on the transparent inorganic bank layer and a second electrode disposed on the opaque bank layer.

The plurality of signal lines may include a plurality of data lines, a plurality of driving voltage lines, and a reference voltage line.

A thickness of the opaque bank layer may be not smaller than a thickness of the transparent inorganic bank layer.

A display device according to embodiments of the disclosure may comprise a plurality of subpixels on a substrate, a plurality of signal lines on the substrate, an overcoat layer disposed on the plurality of signal lines and the substrate, a plurality of organic light emitting diodes on the overcoat layer, each may include a first electrode, a second electrode on the first electrode and an organic light emitting layer between the first and second electrodes and a transparent inorganic bank layer disposed on the overcoat layer at an area between adjacent organic light emitting diodes of the plurality of organic light emitting diodes, at least a portion of the transparent inorganic bank layer may contact the overcoat layer.

The overcoat layer may include a first overcoat layer and a second overcoat layer on the first overcoat layer, the second overcoat layer may have an upper surface and an inclined side surface that may extend from the upper surface, and

the first overcoat layer may have an upper surface that converges with the inclined side surface of the second overcoat layer.

The first electrode may extend from the upper surface of the second overcoat layer and the inclined side surface of the second overcoat layer to the upper surface of the first overcoat layer, and the transparent inorganic bank layer may be on the upper surface of the second overcoat layer and continuously may extend towards the upper surface of the first overcoat layer and contact the upper surface of the first overcoat layer.

The display device may comprise an opaque bank layer on the transparent inorganic bank layer, and the opaque bank layer may be between the adjacent organic light emitting diodes and spaced apart from the first electrode.

A thickness of the opaque bank layer may be greater than a thickness of the transparent inorganic bank layer at a location adjacent to where a reference voltage line may be located, the reference voltage line may be one of a signal line included in the plurality of signal lines.

The second electrode may extend from the organic light emitting diode and extend over the opaque bank layer that may be between the adjacent organic light emitting diodes.

The second electrode continuously and contiguously may extend from one organic light emitting diode of the adjacent organic light emitting diodes to the other organic light emitting diode of the adjacent organic light emitting diodes, and a first electrode of the one organic light emitting diode of the adjacent organic light emitting diodes and a first electrode of the other organic light emitting diode of the adjacent organic light emitting diodes may be spaced apart from each other.

A display device according to embodiments of the disclosure may comprise
a plurality of subpixels on a substrate, a plurality of signal lines on the substrate, an overcoat layer disposed on the plurality of signal lines and the substrate, a plurality of organic light emitting diodes on the overcoat layer, each may include a first electrode, a second electrode on the first electrode and an organic light emitting layer between the first and second electrodes and a transparent inorganic bank layer disposed on the overcoat layer at an area between adjacent organic light emitting diodes of the plurality of organic light emitting diodes, an opaque bank layer on the transparent inorganic bank layer, at least a portion of the opaque bank layer may contact the overcoat layer.

A thickness of the opaque bank layer may be greater than a thickness of the transparent inorganic bank layer.

According to embodiments of the disclosure, as the transparent inorganic bank layer and the opaque bank layer are provided on the inclined surface and lower surface of the recess disposed between the subpixels, it is possible to prevent outgassing or hydrogen migration, enhance side light extraction efficiency, reduce or minimize reflection by external light even without providing a polarizing plate, prevent deterioration of visibility and contrast ratio, and enhance luminance.

According to embodiments of the disclosure, it is possible to reduce parasitic capacitance that occurs between a signal line and the second electrode by having a transparent inorganic bank layer and an opaque bank layer between the signal line and the second electrode in the non-emission area.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate having a plurality of subpixels;
an overcoat layer disposed on the substrate, the overcoat layer including a recess disposed between the subpixels; and
a transparent inorganic bank layer and an opaque bank layer disposed in the recess.

2. The display device of claim 1, wherein the transparent inorganic bank layer is disposed on an inclined surface and a lower surface of the recess.

3. The display device of claim 2, wherein the opaque bank layer is disposed on an upper surface of the transparent inorganic bank layer to be spaced apart from the inclined surface of the recess in an area corresponding to the lower surface of the recess.

4. The display device of claim 2, wherein the transparent inorganic bank layer is disposed to be disconnected on the lower surface of the recess.

5. The display device of claim 2, wherein the transparent inorganic bank layer extends on a portion of an upper surface of the overcoat layer.

6. The display device of claim 5, wherein the transparent inorganic bank layer includes a first portion disposed to extend on the portion of the upper surface of the overcoat layer and a second portion disposed on the inclined surface of the recess, and
wherein a width of the first portion projected onto a plane is larger than a width of the second portion projected onto a plane.

7. The display device of claim 1, wherein the overcoat layer includes:
a first overcoat layer, and
a second overcoat layer positioned on the first overcoat layer in an area corresponding to the subpixels.

8. The display device of claim 7, wherein the recess is disposed between the second overcoat layers positioned in the area corresponding to the subpixels.

9. The display device of claim 8, wherein the transparent inorganic bank layer contacts the first overcoat layer on the lower surface of the recess.

10. The display device of claim 8, wherein the opaque bank layer contacts the first overcoat layer on the lower surface of the recess.

11. The display device of claim 1, wherein the transparent inorganic bank layer includes at least one selected from the group consisting of silicon nitride, silicon oxide, silicon oxynitride, aluminum oxide, and aluminum oxynitride.

12. The display device of claim 1, wherein the opaque bank layer includes at least one selected from the group consisting of carbon black, black pigment, black dye, black resin, graphite powder, gravure ink, black spray, and black enamel.

13. The display device of claim 1, wherein the plurality of subpixels includes at least one colored subpixel among red, green, and blue subpixels, and
wherein a color filter having a color corresponding to the colored subpixel is disposed between the substrate and the overcoat layer.

14. The display device of claim 1, wherein a first electrode, an organic light emitting layer, and a second electrode disposed on the overcoat layer.

15. The display device of claim 14, wherein the first electrode is disposed to extend on a portion of the inclined surface and the upper surface of the recess, and
wherein the transparent inorganic bank layer is disposed on the first electrode and the lower surface of the recess in the recess.

16. The display device of claim 15, wherein the opaque bank layer is disposed on an upper surface of the transparent inorganic bank layer and spaced apart from the inclined surface of the recess, and
wherein the second electrode is disposed on the opaque bank layer.

17. The display device of claim 15, wherein the transparent inorganic bank layer is disposed in an area overlapping the first electrode in the recess.

18. The display device of claim 14, wherein the first electrode is a transparent electrode, and the second electrode is a reflective electrode.

19. A display device, comprising:
a plurality of subpixels including an emission area and a non-emission area; and
a substrate on which a plurality of signal lines defining the plurality of subpixels are disposed,
wherein the emission area includes a recess positioned between the subpixels, and
wherein the non-emission area includes:
an overcoat layer disposed on the plurality of signal lines and the substrate;
a transparent inorganic bank layer disposed on the overcoat layer;
an opaque bank layer disposed on the transparent inorganic bank layer; and
a second electrode disposed on the opaque bank layer.

20. The display device of claim 19, wherein the plurality of signal lines includes a plurality of data lines, a plurality of driving voltage lines, and a reference voltage line.

21. The display device of claim 19, wherein a thickness of the opaque bank layer is not smaller than a thickness of the transparent inorganic bank layer.

22. A display device, comprising:
a plurality of subpixels on a substrate;
a plurality of signal lines on the substrate;
an overcoat layer disposed on the plurality of signal lines and the substrate;
a plurality of organic light emitting diodes on the overcoat layer, each including:
a first electrode;
a second electrode on the first electrode; and
an organic light emitting layer between the first and second electrodes; and
a transparent inorganic bank layer disposed on the overcoat layer at an area between adjacent organic light emitting diodes of the plurality of organic light emitting diodes,
wherein at least a portion of the transparent inorganic bank layer contacts the overcoat layer.

23. The display device of claim 22, wherein the overcoat layer includes a first overcoat layer and a second overcoat layer on the first overcoat layer,
wherein the second overcoat layer has an upper surface and an inclined side surface that extends from the upper surface, and
wherein the first overcoat layer has an upper surface that converges with the inclined side surface of the second overcoat layer.

24. The display device of claim 23, wherein the first electrode extends from the upper surface of the second overcoat layer and the inclined side surface of the second overcoat layer to the upper surface of the first overcoat layer, and
wherein the transparent inorganic bank layer is on the upper surface of the second overcoat layer and continuously extends towards the upper surface of the first overcoat layer and contacts the upper surface of the first overcoat layer.

25. The display device of claim 24, comprising an opaque bank layer on the transparent inorganic bank layer, and
wherein the opaque bank layer is between the adjacent organic light emitting diodes and spaced apart from the first electrode.

26. The display device of claim 25, wherein a thickness of the opaque bank layer is greater than a thickness of the transparent inorganic bank layer at a location adjacent to where a reference voltage line is located,
wherein the reference voltage line is one of a signal line included in the plurality of signal lines.

27. The display device of claim 25, wherein the second electrode extends from the organic light emitting diode and extends over the opaque bank layer that is between the adjacent organic light emitting diodes.

28. The display device of claim 27, wherein the second electrode continuously and contiguously extends from one organic light emitting diode of the adjacent organic light emitting diodes to the other organic light emitting diode of the adjacent organic light emitting diodes, and
wherein a first electrode of the one organic light emitting diode of the adjacent organic light emitting diodes and a first electrode of the other organic light emitting diode of the adjacent organic light emitting diodes are spaced apart from each other.

29. A display device, comprising:
a plurality of subpixels on a substrate;
a plurality of signal lines on the substrate;
an overcoat layer disposed on the plurality of signal lines and the substrate;
a plurality of organic light emitting diodes on the overcoat layer, each including:
a first electrode;
a second electrode on the first electrode; and
an organic light emitting layer between the first and second electrodes; and
a transparent inorganic bank layer disposed on the overcoat layer at an area between adjacent organic light emitting diodes of the plurality of organic light emitting diodes;
an opaque bank layer on the transparent inorganic bank layer,
wherein at least a portion of the opaque bank layer contacts the overcoat layer.

30. The display device of claim 29, wherein a thickness of the opaque bank layer is greater than a thickness of the transparent inorganic bank layer.
